(19) United States
(12) Patent Application Publication
(10) Pub. No.: US 2009/0205696 A1
(43) Pub. Date: Aug. 20, 2009

(54) Thermoelectric Heat Pumps Providing Active Thermal Barriers and Related Devices and Methods

(75) Inventors: David Koester, Burlington, NC (US); Seri Lee, Honolulu, HI (US); Ramaswamy Mahadevan, Chapel Hill, NC (US)

Correspondence Address: MYERS BIGEL SIBLEY & SAJOVEC, PO BOX 37428, RALEIGH, NC, 27627, US

(73) Assignee: Nextreme Thermal Solutions, Inc.

(21) Appl. No.: 12/371,006

(22) Filed: Feb. 13, 2009

Related U.S. Application Data
(60) Provisional application No. 61/066,066, filed on Feb. 15, 2008.

(51) Int. Cl. H01L 35/30; H01L 35/34

(52) U.S. Cl. 136/201; 136/205

(57) ABSTRACT

An electronic device may include a heat generating component and a surface adjacent the heat generating component. A temperature of the heat generating component may be greater than a temperature of the surface adjacent the heat generating component during operation of the electronic device. A thermoelectric heat pump between the surface and the heat generating component may be configured to pump heat from a cold side of the thermoelectric heat pump adjacent the surface toward the heat generating component. Related methods are also discussed.

### RELATED APPLICATION

The present application claims the benefit of priority from U.S. Provisional Application Ser. No. 61/066,066 entitled “Active Thermal Barriers” filed Feb. 15, 2008, the disclosure of which is hereby incorporated herein in its entirety by reference.

### FIELD OF THE INVENTION

The present invention relates to the field of electronics, and more particularly, to thermoelectric devices and methods.

### BACKGROUND

Thermoelectric materials such as p-BiₓSb₂₋ₓTe₃ and n-Bi₂Te₃₋ₓSeₓ may be used to provide heat pumping (e.g., cooling and/or heating) and/or power generation according to the Peltier effect. Thermoelectric materials and structures are discussed, for example, in the reference by Venkatasubramanian et al. entitled “Phonon-Blocking Electron-Transmitting Structures” (18^{th} International Conference On Thermoelectrics, 1999), the disclosure of which is hereby incorporated herein in its entirety by reference. A thermoelectric device, for example, may include one or more thermoelectric pairs with each thermoelectric pair including a p-type thermoelectric element and an n-type thermoelectric element that are electrically coupled in series and that are thermally coupled in parallel, and each of the thermoelectric elements of a pair may be formed of a thermoelectric material such as bismuth telluride (p-type or n-type Bi₂Te₃).

### SUMMARY

According to some embodiments of the present invention, an electronic device may include a heat generating component and a surface adjacent the heat generating component where a temperature of the heat generating component is greater than a temperature of the surface adjacent the heat generating component during operation of the electronic device. A thermoelectric heat pump between the surface and the heat generating component may be configured to pump heat from a cold side of the thermoelectric heat pump adjacent the surface toward the heat generating component.

For example, the surface may be a portion of a surface of a case enclosing the heat generating component therein so that the thermoelectric heat pump is configured to pump heat from the cold side adjacent the portion of the surface of the case toward the heat generating device. According to another example, the surface may be a surface of a backside of a display (such as a liquid crystal display or an organic light emitting diodes (OLED) display) so that the thermoelectric heat pump is configured to pump heat from the cold side adjacent the surface of the backside of the display toward the heat generating device.

The thermoelectric heat pump may include a plurality of thermoelectric elements thermally coupled in parallel between the heat generating component and the surface so that an electrical current tluough the plurality of thermoelectric elements pumps heat from the cold side of the thermoelectric heat pump toward the heat generating component. More particularly, the thermoelectric elements may include n-type and p-type thermoelectric elements that are alternatingly electrically connected in series so that a direction of current through the n-type thermoelectric elements is opposite a direction of current flow through the p-type thermoelectric elements.

The thermoelectric heat pump may include a hot side heat spreader so that the plurality of thermoelectric elements are thermally coupled in parallel between the hot side heat spreader and the surface and so that the hot side heat spreader is between the plurality of thermoelectric elements and the heat generating component. Moreover, the hot side heat spreader may be spaced apart from the heat generating component to provide a thermally insulating gap therebetween. The thermally insulating gap, for example, may include an air gap and/or a layer of a thermally insulating material (such as aerogel, silicon oxide, etc.) between the hot side heat spreader and the heat generating component.

The thermoelectric heat pump may include a cold side heat spreader so that the plurality of thermoelectric elements are thermally coupled in parallel between the cold side heat spreader and the heat generating component and so that the cold side heat spreader is between the plurality of thermoelectric elements and the surface. Moreover, the cold side heat spreader may be spaced apart from the surface to provide a thermally insulating gap therebetween. The thermally insulating gap, for example, may include an air gap and/or a layer of a thermally insulating material between the cold side heat spreader and the surface.

The heat generating component may include an active heat generating electronic device (e.g., a microelectronic device, a microprocessor, an application specific integrated circuit, a memory, etc.), and/or the heat generating component may include a passive heat generating source (e.g., a heat sink, a remote heat exchanger, a heat pipe, etc.). The thermoelectric heat pump may be a first thermoelectric heat pump, and a second thermoelectric heat pump may be provided between the surface and the heat generating component. More particularly, the second thermoelectric heat pump may be configured to pump heat from a cold side of the second thermoelectric heat pump adjacent the heat generating component toward the surface.

According to other embodiments of the present invention, a method may be provided to operate an electronic device including a heat generating component and a surface adjacent the heat generating component, where a temperature of the heat generating component is greater than a temperature of the surface. The method may include thermoelectrically pumping heat from a cold side of a thermoelectric heat pump adjacent the surface toward the heat generating component wherein the thermoelectric heat pump is between the surface and the heat generating component.

For example, the surface may be a portion of a surface of a case enclosing the heat generating component therein so that thermoelectrically pumping heat includes thermoelectrically pumping heat from the cold side adjacent the portion of the surface of the case toward the heat generating device. According to another example, the surface may be a surface of a backside of a display so that thermoelectrically pumping includes thermoelectrically pumping heat from the cold side adjacent the surface of the backside of the display toward the heat generating device.

Thermoelectrically pumping heat may include providing an electrical current through a plurality of thermoelectric elements that are thermally coupled in parallel between the heat generating component and the surface to thermoelectrically pump heat away from the surface and toward the heat generating component. Moreover, the thermoelectric elements may include n-type and p-type thermoelectric elements that are alternatingly electrically connected in series so that a direction of current through the n-type thermoelectric elements is opposite a direction of current through the p-type thermoelectric elements.

The heat generating component may include an active heat generating electronic device (e.g., microelectronic device, a microprocessor, an application specific integrated circuit, a memory, an amplifier, etc.), and/or the heat generating component may include a passive heat generating source (e.g., a heat sink, a remote heat exchanger, a heat pipe, etc.). The thermoelectric heat pump may be a first thermoelectric heat pump, and a second thermoelectric heat pump may be provided between the surface and the heat generating component. Moreover, heat may be thermoelectrically pumped from a cold side of the second thermoelectric heat pump adjacent the heat generating component toward the surface while thermoelectrically pumping heat from the cold side of the first thermoelectric heat pump toward the heat generating component.

### BRIEF DESCRIPTION OF THE DRAWINGS

FIG. 1A is a cross sectional schematic diagram illustrating a computer or electronics system case wall (or skin) and a heat generating component.

FIG. 1B is a graph illustrating case wall temperatures across a surface of the case of FIG. 1A.

FIG. 2A is a model illustrating thermal resistances of the structure of FIG. 1A, and FIG. 2B is a graph illustrating heat flow according to the model of FIG. 2A.

FIG. 3A is a cross sectional schematic diagram illustrating a computer or electronics system case wall (or skin) and a heat generating component with insulation therebetween.

FIG. 3B is a graph illustrating case wall temperatures across a surface of the case of FIG. 3A.

FIG. 4A is a model illustrating thermal resistances of the structure of FIG. 3A, and FIG. 4B is a graph illustrating heat flow according to the model of FIG. 3A.

FIG. 5A is a cross sectional schematic diagram illustrating a computer or electronics system case wall (or skin) and a heat generating component with a thermoelectric heat pump providing an active thermal barrier therebetween according to some embodiments of the present invention.

FIG. 5B is a graph illustrating case wall temperatures across a surface of the case of FIG. 5A.

FIG. 6A is a model illustrating thermal resistances of the structure of FIG. 5A, and FIG. 6B is a graph illustrating heat flow according to the model of FIG. 5A.

FIG. 7 is a cross sectional view illustrating a thermoelectric heat pump providing an active thermal barrier according to some embodiments of the present invention.

FIG. 8 is a cross sectional view illustrating an electronic device including a thermoelectric heat pump mounted on an inside surface of case according to some embodiments of the present invention.

FIG. 9 is a cross sectional view illustrating an electronic device including a thermoelectric heat pump mounted on a heat generating device according to some embodiments of the present invention.

FIG. 10 is a thermal circuit and graph illustrating heat flow between a case and a heat generating component according to some embodiments of the present invention.

FIGS. 11-14 are cross sectional views of electronic devices including thermoelectric heat pumps used to provide active thermal barriers according to still other embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Examples of embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

In many electronic systems today, high heat output of components in the system may cause relatively high temperatures on the exterior of the product. This excess temperature may be of concern, particularly if the system exterior (sometimes called the product “skin” or “case”) comes in contact with the human body.

One example of such a problem is in the laptop computer. There are documented instances of laptop case (or skin) temperatures exceeding 45° C. (113° F.). This may lead to discomfort and in some instances may require that the consumer turn off the computer. A reduction of as little as 5° C. may provide enough relief to satisfy the consumer.

Several problems may contribute to the relatively high surface temperatures in laptops and other electronics systems. First, modern microelectronic devices, microprocessors, ASICs (Application Specific Integrated Circuits), memories, and other components are consuming more power and therefore generating more heat. Second, products are shrinking in size and more components are squeezed into smaller volumes leading to higher heat densities. Third, system-level heat rejection systems are running out of performance headroom. These factors may lead to heat build-up inside the case resulting in high interior temperatures that can spill over into hot spots on the case surface.

Standard methods of thermally insulating the case to reduce these hot spots may be largely ineffective due to limits on space available inside the case. In many situations, constraints on this space may preclude an insulation thickness sufficient to reduce the exterior surface temperature. Moreover, use of insulation may not provide an improvement and in some instances, may be worse than using no insulation as discussed in greater detail below.

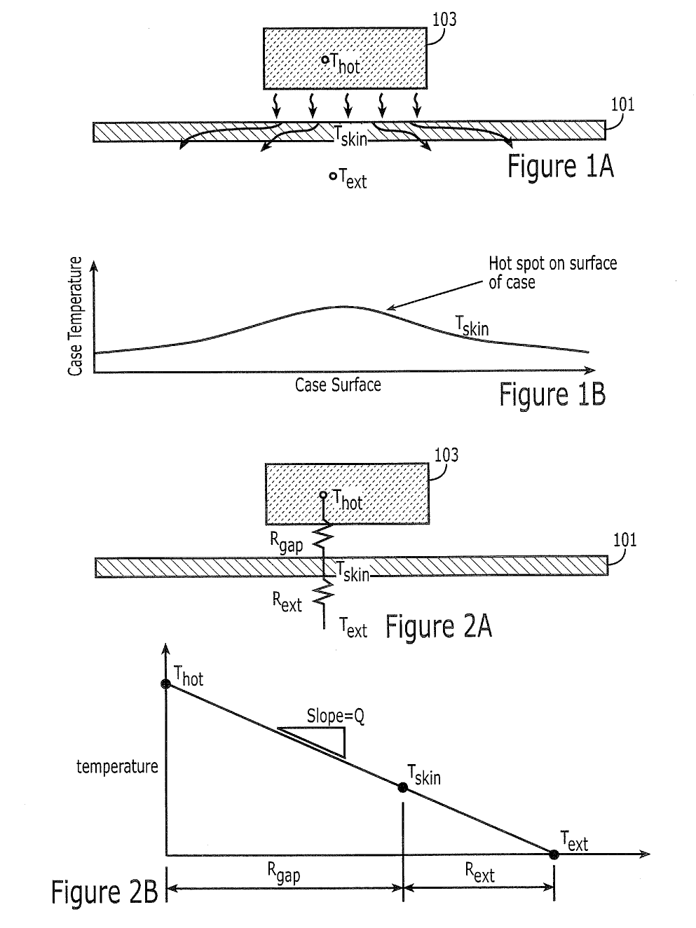

FIG. 1A is a cross sectional schematic diagram illustrating a computer or electronics system case wall (or skin) 101 and a heat generating component 103. FIG. 1B is a graph illustrating case wall temperatures across a surface of the case 101 of FIG. 1A. The air outside the case 101 (the exterior air) is at a temperature, Text, that is less than a temperature Tint of the air inside the case ( the interior air). Under such a condition, heat from inside the case 101 may naturally flow through the case 101 wall to the to the exterior air outside the case 101. FIG. 1A shows arrows that represent heat passing from the heat generating component 103 (or heat source) through the case 101 wall. Non-uniform temperatures inside the case 101 may translate to non-uniform temperature profiles on the exterior of the case 101 (or skin) as shown in the plot of FIG. 1B. In FIG. 1A, only air is provided between the heat generating component 103 and the case 101 wall.

As shown in FIGS. 2A and 2B, heat transfer of the structure of FIG. 1A can be modeled in a one-dimensional fashion. Here, a thermal resistance from the heat generating component 101 to the ambient (external air) is a combination of a thermal resistance Rgap of an air gap between the heat generating component 103 and the case 101, and a thermal resistance Rext of an external air barrier resistance. A thermal resistance of the case 101 itself may be negligible. A slope of the line in the temperature vs. thermal resistance plot of FIG. 2B may be the heat flow, Q.

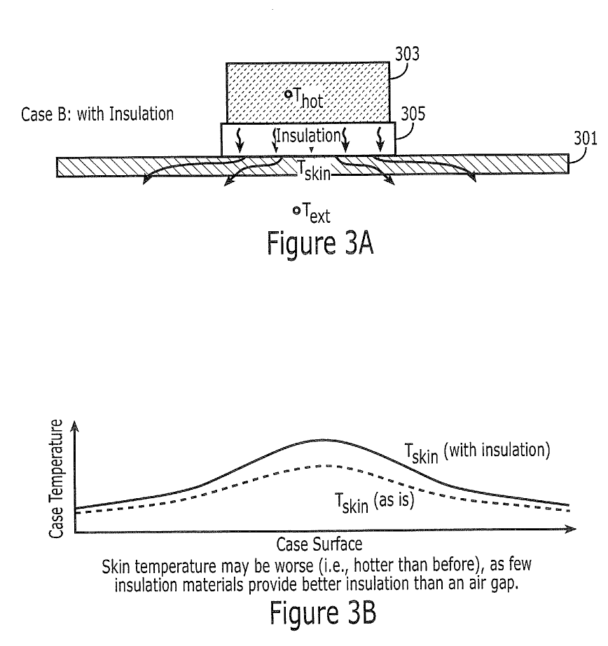

FIG. 3A is a cross sectional schematic diagram illustrating a computer or electronics system case wall (or skin) 301 and a heat generating component 303 with insulation 305 (other than air) therebetween. FIG. 3B is a graph illustrating case wall temperatures across a surface of the case 303 of FIG. 3A. As shown in FIGS. 3A and 3B, the air gap is replaced by insulation of some type. Because the thermal resistance of the insulation 305 may actually be less than that of an air gap, the temperature of the case 301 (or skin) directly below the heat generating component 303 may be hotter than that discussed above with respect to FIGS. 1A-B and 2A-B.

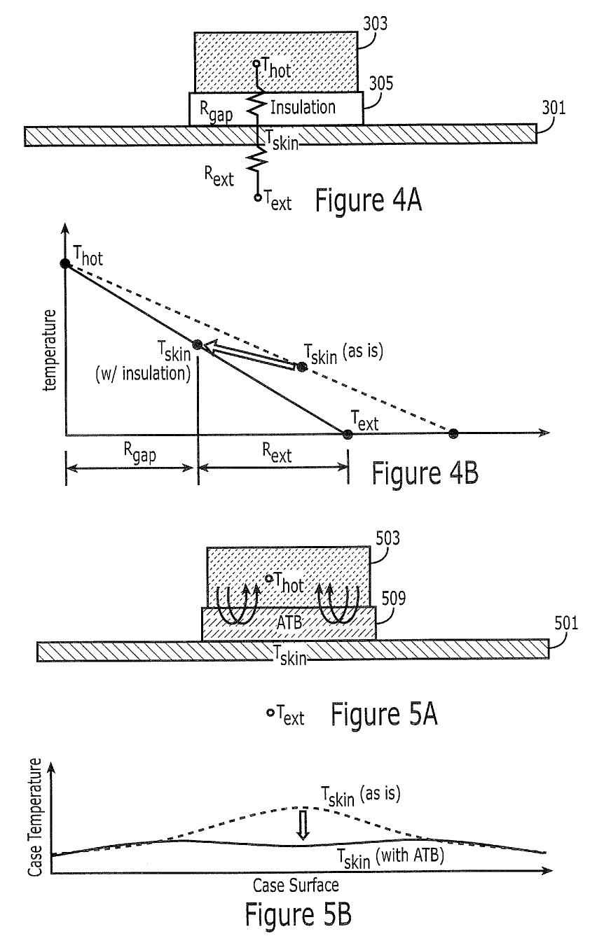

As shown in FIGS. 4A and 4B, heat transfer of the structure of FIG. 3A can be modeled in a one-dimensional fashion. Here, a thermal resistance from the heat generating component 303 to the ambient (external air) is a combination of a thermal resistance Rgap of insulation 305 between the heat generating component 303 and the case 301, and a thermal resistance Rext of an external air barrier resistance. A thermal resistance of the case 301 itself may be negligible. A slope of the line in the temperature vs. thermal resistance plot of FIG. 4B may be the heat flow, Q. The graph of FIG. 4B shows a comparison of heat transfer of the structure of FIG. 3A (solid line) and heat transfer of the structure of FIG. 1A (dashed line). As shown in FIG. 4A, the actual case 301 (or skin) temperature of the structure of FIG. 3A may increase relative to the structure of FIG. 1A.

In FIG. 5A, a thermoelectric heat pump 509 (also referred to as a thermoelectric cooler or TEC) is provided between heat generating component 503 and case 501 (or skin) instead of an insulator of FIG. 3A or an air gap of FIG. 1A. As shown in FIG. 5A, a cold side of the thermoelectric heat pump is placed adjacent to the case 501 (or skin) of the system. The thermoelectric heat pump 509 may create a temperature inversion opposite of the normal thermal gradient to repel heat back toward the heat generating component 503 as shown by the arrows. The thermoelectric heat pump 509 may thus provide an active thermal barrier (or ATB) to provide a thermal profile on the case 501 (or skin) as shown in the graph of FIG. 5B that may be an improvement over the thermal profiles of the structures of FIGS. 1A and 3A.

Case 501, for example, may be a case of an electronic device (e.g., a laptop computer, notebook computer, mobile radiotelephone, a handheld computer, a personal digital assistant, a handheld gaming device, a digital media player, etc.), and case 501 may enclose heat generating component 503 and other elements (e.g., a microprocessor, a memory, a display, a transmitter, a receiver, a speaker, a microphone, etc.) providing functionality of the electronic device. Moreover, thermoelectric heat pump 509 may extend along only a portion of a surface of case 501 so that other portions of the surface of case 501 are free of thermoelectric heat pump 509.

Heat transfer in the structure of FIG. 5A (with thermoelectric heat pump 509 providing an active thermal barrier or ATB) may be considerably different than heat transfer in the structures of FIGS. 1A and 3A as shown in the graph of FIG. 5B where the solid line shows temperatures across case 501 of FIG. 5A and the dashed line shows temperatures across case 101 of FIG. 1B.

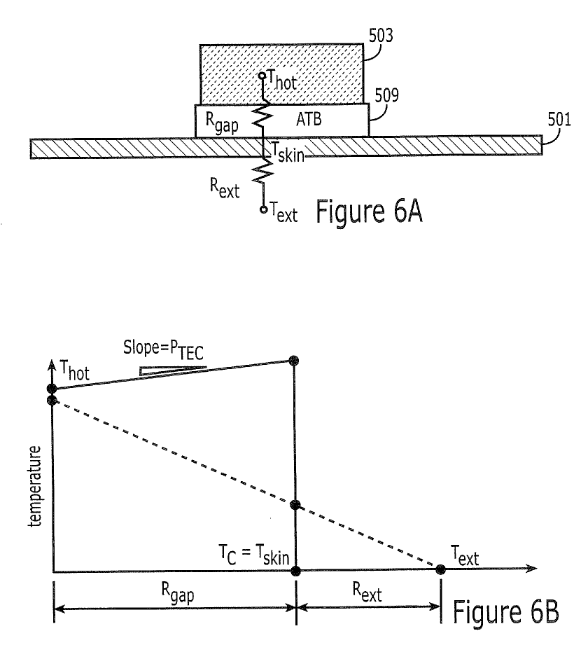

As shown in FIGS. 6A and 6B, heat transfer of the structure of FIG. 5A can be modeled in a one-dimensional fashion. Here, a thermal resistance from the heat generating component 503 to the ambient (external air) is a combination of a thermal resistance Rgap of the thermoelectric heat pump 509 providing the active thermal barrier (ATB) between the heat generating component 503 and the case 501, and a thermal resistance Rext of an external air barrier resistance. A thermal resistance of the case 501 itself may be negligible. A slope of the solid line in the temperature vs. thermal resistance plot of FIG. 6B may be the heat flow, Q. The graph of FIG. 6B shows a comparison of heat transfer of the structure of FIG. 5A (solid line) and heat transfer of the structure of FIG. 1A (dashed line). As shown in FIG. 6A, the actual case 501 (or skin) temperature of the structure of FIG. 5A may be substantially the same as the external temperature Text.

As shown in FIG. 6B, the thermoelectric heat pump 509 may provide a temperature inversion resulting in a reversal of heat flow back toward the heat generating component 503. An amount of heat transferred back toward the heat generating component may be the input power to the thermoelectric heat pump 509. Because the thermoelectric heat pump 509 is an active device, the cold side of the thermoelectric heat pump 509 may be controlled to substantially match a temperature Text of the exterior air and/or a temperature Tc of the case 509 so that substantially no heat flows from outside the case 501 to inside the case 501.

By providing a pumping of heat toward the heat generating component 503, the thermoelectric heat pump 509 may provide substantially no heat flow from the heat generating component 503 toward case 509. Relative to the case 501, the thermoelectric heat pump 509 may effectively provide a near perfect thermal barrier and/or insulator. While a temperature of the heat generating component 503 and/or a temperature at an interface between heat generating component 503 and a hot side of thermoelectric heat pump 509 may be increased due to power input into the thermoelectric heat pump 509, the active thermal barrier effect of the thermoelectric heat pump 509 may be provided with a relatively low power input so that the temperature is not increased significantly.

In the cross sectional views of FIGS. 5A and 6A, the heat generating component 503 may be an active heat generating electronic device such as an integrated circuit electronic device, and the thermoelectric heat pump 509 providing an active thermal barrier may operate according to the Peltier effect. For example, the heat generating component 503 may be a microelectronic device, a microprocessor, an ASIC, a memory, an amplifier, etc., and the thermoelectric heat pump 509 may include a plurality of n-type and p-type thermoelectric elements electrically coupled in series and thermally coupled in parallel between the heat generating component 503 and the case 501 (or skin) of the system. According to other embodiments of the present invention, the heat generating component 503 may be a passive heat generating component such as a heat sink, a remote heat exchanger, and/or a heat pipe.

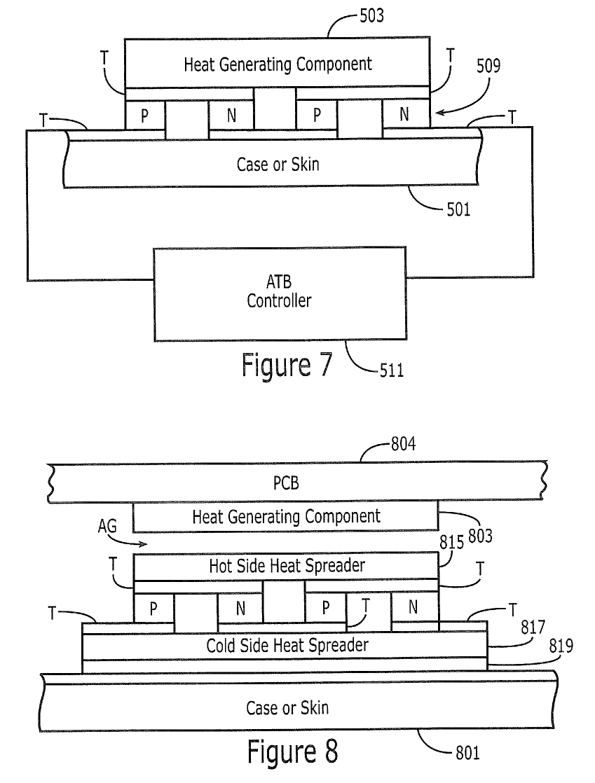

As shown in FIG. 7, the thermoelectric heat pump 509 providing the active thermal barrier may include a plurality of p-type thermoelectric elements P and n-type thermoelectric elements N electrically coupled in series using electrically conductive traces T. More particularly, the thermoelectric elements P and N may be alternatingly connected in series, and thermally connected in parallel between the heat generating component 503 and the case 501 (or skin) of the system. Moreover, the p-type and n-type thermoelectric elements P and N may be formed of a material having a relatively high Seebeck coefficient such as bismuth telluride (Bi₂Te₃), lead telluride (PbTe), and/or silicon-germanium (SiGe). Accordingly, the controller 511 may be configured to generate an electrical current through the traces T and thermoelectric elements P and N so that heat is pumped away from the case 511 (or skin) toward heat generating 503 thereby reducing a temperature of the case 501 (or skin) directly adjacent to the heat generating component 503. While thermoelectric elements of opposite conductivity types are shown, a single conductivity type may be used with electrical coupling provided so that current flows in only one direction through the thermoelectric element or elements of the same conductivity type.

An active thermal barrier may be provided according to embodiments of the present invention using thermoelectric heat pump 509 between a heat generating component 503 such as an active heat generating component (e.g., a microelectronic device, a microprocessor, an ASIC, a memory, an amplifier, etc.) or a passive heat generating component (e.g., a heat sink, a remote heat exchanger, a heat pipe, etc.) and a case 501 of a system such as a laptop computer to reduce a temperature of a hotspot on the case 501. An active thermal barrier may thus be used to reduce a temperature of a hotspot on a bottom of a laptop computer that may be expected to be in contact with a user's lap. An active thermal barrier may also be used with other electronic devices that may be expected to be used in contact with a user's body, such as a mobile radiotelephone, a handheld computer, a personal digital assistant, a handheld gaming device, a digital media player, etc. Moreover, active thermal barriers may be used to protect other components of a system (e.g., an display) from heat generated by the heat generating component 503. While controller 511 and heat generating component 503 are shown on opposite sides of case 501 for ease of illustration, controller 511 and heat generating component 503 may be provided on a same side of case 501 (e.g., inside case 501).

FIG. 8 is a cross sectional view illustrating electronic systems including thermoelectric heat pumps providing active thermal barriers according to some embodiments of the present invention. As shown in FIG. 8, an active thermal barrier may be provided using a thermoelectric heat pump including p-type and n-type thermoelectric elements P and N thermally coupled in parallel between thermally conductive hot side and cold side heat spreaders 815 and 817. Moreover, electrically conductive traces T on heat spreaders 815 and 817 may provide electrical connections so that the n-type and p-type thermoelectric elements P and N are alternatingly electrically connected in series and so that a direction of current through the n-type thermoelectric elements is opposite a direction of current flow through the p-type thermoelectric elements. Each of the thermally conductive heat spreaders 815 and 817 may include an electrically insulating and thermally conductive material (such as aluminum oxide), and/or each of the thermally conductive heat spreaders 815 and 817 may include an electrically and thermally conductive material (such as copper) with a thin layer of an electrically insulating material (such as silicon oxide, silicon nitride, etc.) thereon to provide electrical isolation between traces T.

As shown in FIG. 8, the thermoelectric heat pump may be mechanically mounted on an inside surface of case 801, for example, using an adhesive, and an air gap AG may be provided between the heat generating component 803 and the hot side heat spreader 815. Moreover, an optional layer 819 of a thermally insulating material (such as aerogel, silicon oxide, etc.) may be provided between the cold side heat spreader 817 and case 801 to increase a thermal resistance therebetween. While an air gap AG is shown between hot side heat spreader 815 and heat generating component 803 in FIG. 8, a layer of a thermally insulating material (such as aerogel silicon oxide, etc.) may fill some or all of the gap between hot side heat spreader 815 and heat generating component 803. Moreover, the heat generating component 803 may be electrically and/or mechanically coupled to a printed circuit board (PCB) or other supporting structure enclosed within case 801.

Case 801, for example, may be a case of an electronic device (e.g., a laptop computer, notebook computer, mobile radiotelephone, a handheld computer, a personal digital assistant, a handheld gaming device, a digital media player, etc.), and case 801 may enclose heat generating component 803 and other elements (e.g., a microprocessor, a memory, a display, a transmitter, a receiver, a speaker, a microphone, etc.) providing functionality of the electronic device. Moreover, thermoelectric heat pump (including heat spreaders 815 and 817, traces T, and thermoelectric elements P and N) may extend along only a portion of a surface of case 801 so that other portions of the surface of case 801 are free of the thermoelectric heat pump.

Accordingly, the thermoelectric heat pump may be configured to pump heat from the cold side heat spreader 817 to the hot side heat spreader 815 in response to a current through traces T and thermoelectric elements P and N to thereby reduce heat flow from heat generating component 803 toward case 801. By thermally isolating hot side heat spreader 815 from heat generating component 803 using air gap AG and/or by thermally isolating cold side heat spreader 817 from case 801 using layer 819 of a thermally insulating material (such as aerogel, silicon oxide, etc.), a current (and thus power) used to create a desired temperature inversion may be reduced thereby reducing power consumption and/or reducing additional heat introduced into the system. In other words, by intentionally introducing thermal impedance on one or both sides of the thermoelectric heat pump, an efficiency of operation as an active thermal barrier may be improved. The heat generating component 803 may be an active heat generating electronic device such as a microelectronic device, a microprocessor, an application specific integrated circuit, a memory, and/or an amplifier, or the heat generating component 803 may be a passive heat generating source such as a heat sink, a remote heat exchanger, a heat pipe, etc.

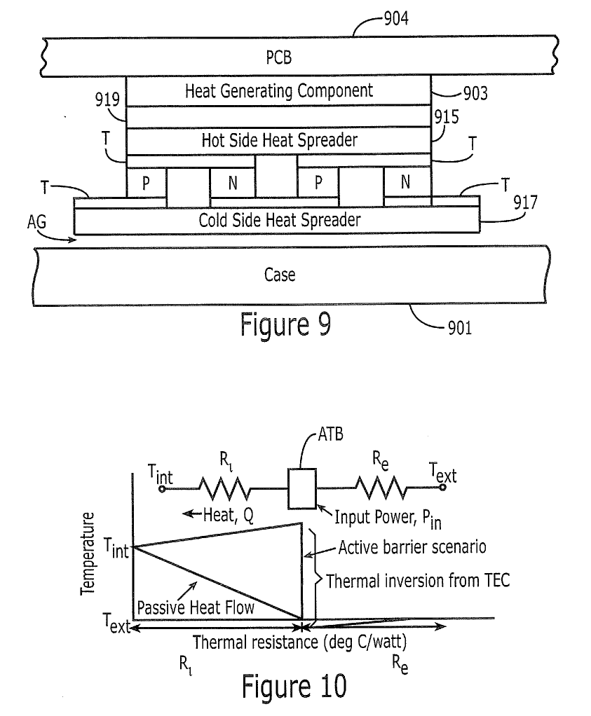

FIG. 9 is a cross sectional view illustrating electronic systems including thermoelectric heat pumps providing active thermal barriers according to some other embodiments of the present invention. As shown in FIG. 9, an active thermal barrier may be provided using a thermoelectric heat pump including p-type and n-type thermoelectric elements P and N thermally coupled in parallel between thermally conductive hot side and cold side heat spreaders 915 and 917. Moreover, electrically conductive traces T on heat spreaders 915 and 917 may provide electrical connections so that the n-type and p-type thermoelectric elements P and N are alternatingly electrically connected in series and so that a direction of current through the n-type thermoelectric elements is opposite a direction of current flow through the p-type thermoelectric elements. Each of the thermally conductive heat spreaders 915 and 917 may include an electrically insulating and thermally conductive material (such as aluminum oxide), and/or each of the thermally conductive heat spreaders 915 and 917 may include an electrically and thermally conductive material (such as copper) with a thin layer of an electrically insulating material (such as silicon oxide, silicon nitride, etc.) thereon to provide electrical isolation between traces T.

As further shown in FIG. 9, the thermoelectric heat pump may be mechanically mounted on heat generating component 903, for example, using an adhesive, and an air gap AG may be provided between cold side heat spreader 917 and case 901. Moreover, an optional layer 919 of a thermally insulating material (such as aerogel, silicon oxide, etc.) may be provided between the hot side heat spreader 915 and heat generating component 903 to increase a thermal resistance therebetween. While an air gap AG is shown between cold side heat spreader 917 and case 901 in FIG. 9, a layer of a thermally insulating material (such as aerogel, silicon oxide, etc.) may fill some or all of the gap between cold side heat spreader 917 and case 901. Moreover, the heat generating component 903 may be electrically and/or mechanically coupled to a printed circuit board (PCB) or other supporting structure enclosed within case 901.

Case 901, for example, may be a case of an electronic device (e.g., a laptop computer, notebook computer, mobile radiotelephone, a handheld computer, a personal digital assistant, a handheld gaming device, a digital media player, etc.), and case 901 may enclose heat generating component 903 and other elements (e.g., a microprocessor, a memory, a display, a transmitter, a receiver, a speaker, a microphone, etc.) providing functionality of the electronic device. Moreover, thermoelectric heat pump (including heat spreaders 915 and 917, traces T, and thermoelectric elements P and N) may extend along only a portion of a surface of case 901 so that other portions of the surface of case 901 are free of the thermoelectric heat pump.

Accordingly, the thermoelectric heat pump may be configured to pump heat from the cold side heat spreader 917 to the hot side heat spreader 915 in response to a current through trances T and thermoelectric elements P and N to thereby reduce heat flow from heat generating component 903 toward case 901. By thermally isolating cold side heat spreader 917 from case 901 using air gap AG and/or by thermally isolating hot side heat spreader 915 from heat generating component 903 using layer 919 of thermally insulating material (such as aerogel, silicon oxide, etc.), a current (and thus power) used to create a desired temperature inversion may be reduced thereby reducing power consumption and/or reducing additional heat introduced into the system. In other words, by intentionally introducing thermal impedance on one or both sides of the thermoelectric heat pump, an efficiency of operation as an active thermal barrier may be improved. Moreover, by maintaining air gap AG between cold side heat spreader 917 and case 901, an air flow may be maintained therebetween (for example, using a cooling fan) to dissipate heat from the system. The heat generating component 903 may be an active heat generating electronic device such as a microelectronic device, a microprocessor, an application specific integrated circuit, a memory, and/or an amplifier, or the heat generating component 903 may be a passive heat generating source such as a heat sink and/or a remote heat exchanger, a heat pipe, etc.

FIG. 10 is a thermal circuit and graph illustrating heat flow between a case and a heat generating component according to some embodiments of the present invention. Active thermal barrier ATB may be provided using a thermoelectric heat pump configured to pump heat toward the heat generating component, thermal resistance Ri may be an internal thermal resistance between a hot side of the active thermal barrier and the heat generating component, and external thermal resistance Re may be a thermal resistance between a cold side of the active thermal barrier and an outside of the case. As shown, the active thermal barrier may provide a sufficient temperature inversion between the heat generating component and the case so that heat flow from the heat generating component to the case is essentially blocked. By providing sufficient thermal isolation for the active thermal barrier (e.g., by providing sufficiently high thermal resistances Ri and/or Re), an input power to the active thermal barrier may be reduced and/or a transfer of heat from outside the case to inside the case may be reduced.

In the example of FIG. 8, the thermal resistance Ri may be substantially provided by air gap AG, thermal resistance Re may be substantially provided by layer 819 of thermally insulating material and/or case 901, and active thermal barrier ATB may be provided by the thermoelectric heat pump (including thermoelectric elements P and N, heat spreaders 815 and 817, and traces T). In the example of FIG. 9, the thermal resistance Ri may be substantially provided by layer 919 of thermally insulating material, thermal resistance Re may be substantially provided by air gap AG and/or case 901, and active thermal barrier ATB may be provided by the thermoelectric heat pump (including thermoelectric elements P and N., heat spreaders 915 and 917, and traces T). To their knowledge, the Applicants are the first to realize that by operating a thermoelectric heat pump to pump heat toward a heat generating device, a temperature inversion may be provided thereby reducing an undesirable transfer of heat to a case or other component. In other words, by operating a thermoelectric heat pump to provide a direction of heat pumping that is opposite the conventional usage, the Applicants have provided an active thermal barrier. Moreover, the Applicants are also the first to realize that an efficiency of operation of a thermoelectric heat pump as an active thermal barrier may be improved by increasing a thermal resistance of couplings to hot and/or cold side heat spreaders of the thermoelectric heat barrier.

According to additional embodiments of the present invention, a thermoelectric heat pump may be used to provide an active thermal barrier between a heat generating component and another active component of an electronic system. By way of example, a thermoelectric heat pump may be used to provide an active thermal barrier between a heat generating source and a backside of a display, such as a liquid crystal display (LCD) or an organic light emitting diodes (OLED) display.

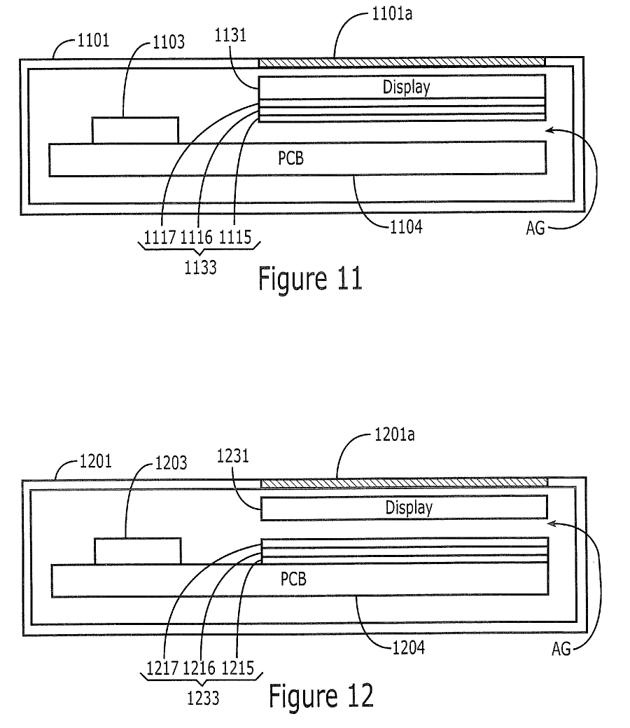

FIGS. 11-14 are cross sectional views illustrating use of thermoelectric heat pumps as active thermal barriers to protect a display (such as a liquid crystal display (LCD) or an organic light emitting diodes (OLED) display) from heat generated within an electronic device including the display. As shown in FIG. 11, an electronic device may include a heat generating component 1103 electrically and mechanically coupled to a printed circuit board 1104 and enclosed within a case 1101 (including a transparent region 1101 a) together with a display 1131 (such as a liquid crystal display or an organic light emitting diodes (OLED) display). The heat generating component 1103 may be an active electronic heat generating device (e.g., a microelectronic device, a microprocessor, an application specific integrated circuit, a memory, a power amplifier, etc.), and heat from the heat generating component 1103 may conduct through the printed circuit board and radiate toward display 1131. Accordingly, thermoelectric heat pump 1133 may be provided on a backside of display 1131 between display 1131 and printed circuit board 1104 to reduce heat flow from printed circuit board 1104 to display 1131. Thermoelectric heat pump 1133 may be provided as discussed above with respect to FIG. 8 with a cold side heat spreader 1117 mechanically coupled to the backside of display 1131, with a hot side heat spreader 1115 adjacent printed circuit board, and with thermoelectric elements and traces 1116 between hot and cold side heat spreaders 1115 and 1117. Particular arrangements of thermoelectric elements and traces are not repeated in FIG. 11 for ease of illustration. Moreover, an air gap AG and/or a layer of a thermally insulating material (such as aerogel, silicon oxide, etc.) may be provided between hot side heat spreader 1115 and printed circuit board 1104.

Thermoelectric heat pump 1133 may operate to provide an active thermal barrier between display 1131 and printed circuit board 1104 (or other heat generating component) in a manner similar to that discussed above with respect to FIG. 8 where a thermoelectric heat pump is mechanically coupled to the colder of the two elements. In particular, the thermoelectric heat pump 1131 may be configured to pump heat in a direction from display 1131 toward printed circuit board 1104. Moreover, an efficiency of the thermoelectric heat pump 1133 as an active thermal barrier may be improved by providing thermal insulation (such as air gap AG) in the path of heat flow between display 1131 and printed circuit board 1133. While air gap AG is shown by way of example, one or more thermally insulating materials/layers may be provided between cold side heat spreader 1117 and display 1131, between hot side heat spreader 1115 and air gap AG, and/or between air gap AG and printed circuit board 1104.

In FIG. 12, an electronic device may include a heat generating component 1203 electrically and mechanically coupled to a printed circuit board 1204 and enclosed within a case 1201 (including a transparent region 1201 a) together with a display 1231 (such as a liquid crystal display or an organic light emitting diodes (OLED) display). The heat generating component 1203 may be an active electronic heat generating device (e.g., a microelectronic device, a microprocessor, an application specific integrated circuit, a memory, a power amplifier, etc.), and heat from the heat generating component 1203 may conduct through the printed circuit board 1204 and radiate toward display 1231. Accordingly, thermoelectric heat pump 1233 may be provided on printed circuit board 1204 between display 1231 and printed circuit board 1204 to reduce heat flow from printed circuit board 1204 to display 1231. Thermoelectric heat pump 1233 may be provided as discussed above with respect to FIG. 9 with a hot side heat spreader 1215 mechanically coupled to printed circuit board 1204, with a cold side heat spreader 1217 adjacent display 1231, and with thermoelectric elements and traces 1216 between hot and cold side heat spreaders 1215 and 1217. Particular arrangements of thermoelectric elements and traces are not repeated in FIG. 12 for ease of illustration. Moreover, an air gap AG and/or a layer of a thermally insulating material (such as aerogel, silicon oxide, etc.) may be provided between cold side heat spreader 1217 and printed circuit board 1204.

Thermoelectric heat pump 1233 may operate to provide an active thermal barrier between display 1231 and printed circuit board 1204 (or other heat generating component) in a manner similar to that discussed above with respect to FIG. 9 where a thermoelectric heat pump is mechanically coupled to the hotter of the two elements. In particular, the thermoelectric heat pump 1231 may be configured to pump heat in a direction from display 1231 toward printed circuit board 1204. Moreover, an efficiency of the thermoelectric heat pump 1233 as an active thermal barrier may be improved by providing thermal insulation (such as air gap AG) in the path of heat flow between display 1131 and printed circuit board 1133. While air gap AG is shown by way of example, one or more thermally insulating materials/layers may be provided between cold side heat spreader 1117 and air gap AG, between display 1231 and air gap AG, and/or between hot side heat spreader 1115 and printed circuit board 1204.

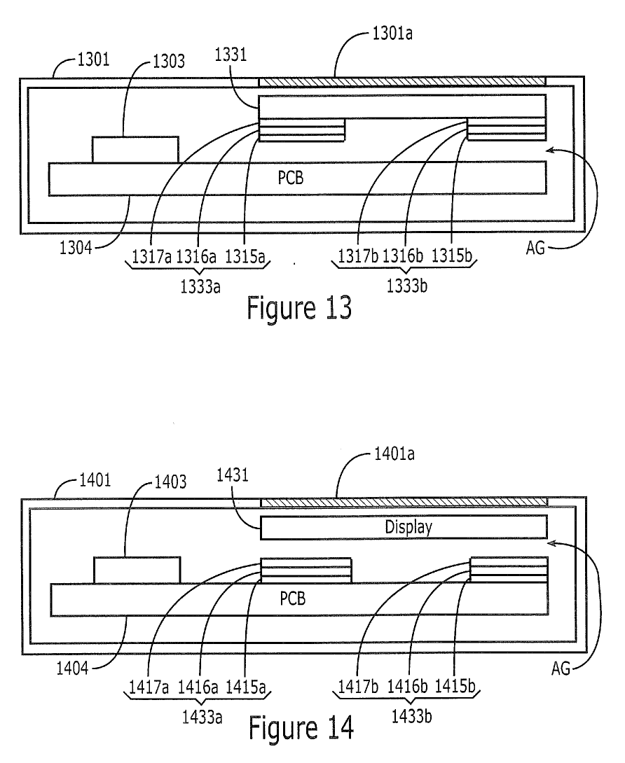

As shown in FIG. 13, an electronic device may include a heat generating component 1303 electrically and mechanically coupled to a printed circuit board 1304 and enclosed within a case 1301 (including a transparent region 1301a) together with a display 1331 (such as a liquid crystal display or an organic light emitting diodes (OLED) display). The heat generating component 1303 may be an active electronic heat generating device (e.g., a microelectronic device, a microprocessor, an application specific integrated circuit, a memory, a power amplifier, etc.), and heat from the heat generating component 1303 may conduct through the printed circuit board and radiate toward display 1331. Accordingly, thermoelectric heat pumps 1333a and 1333b may be provided on abackside of display 1331 between display 1331 and printed circuit board 1304 to reduce heat flow from printed circuit board 1304 to display 1331 and/or to reduce a temperature gradient across the display. Thermoelectric heat pumps 1333a and 1333b may be provided as discussed above with respect to FIGS. 8 and 11 with cold side heat spreaders 1317a and 1317b mechanically coupled to the backside of display 1331, with hot side heat spreaders 1315a and 1315b adjacent printed circuit board 1304, and with thermoelectric elements and traces 1316a and 1316b between respective hot and cold side heat spreaders 1315a-b and 1317a-b. Particular arrangements of thermoelectric elements and traces are not repeated in FIG. 13 for ease of illustration. Moreover, an air gap AG and/or a layer of a thermally insulating materials (such as aerogel, silicon oxide, etc.) may be provided between hot side heat spreaders 1315a and 1315b and printed circuit board 1304.

Thermoelectric heat pumps 1333a and 1333b may operate to provide separately controlled active thermal barriers between display 1331 and printed circuit board 1304 (or other heat generating component) in a manner similar to that discussed above with respect to FIGS. 8 and 11 where a thermoelectric heat pump is mechanically coupled to the colder of the two elements. For example, both of thermoelectric heat pumps 1333a and 1333b may be configured to pump heat in a direction from display 1331 toward printed circuit board 1304, with greater input power and/or current for heat pump 1333a (closer to heat generating component 1303) and lesser input power and/or current for heat pump 1333b (more distant from heat generating component 1303) to reduce a temperature gradient across display 1331. In an alternative, thermoelectric heat pump 1333a may be configured to pump heat in a direction from display 1331 toward printed circuit board 1304 while thermoelectric heat pump 1333b may be configured to pump heat in a direction from printed circuit board 1304 toward display 1331 to reduce a temperature gradient across display 1331. Moreover, efficiencies of thermoelectric heat pumps 1333a and/or 1333b as active thermal barriers may be improved by providing thermal insulation (such as air gap AG) in the paths of heat flow between display 1331 and printed circuit board 1333. While air gap AG is shown by way of example, one or more thermally insulating materials/layers may be provided between cold side heat spreaders 1317a-b and display 1931, between hot side heat spreaders 1315a-b and air gap AG, and/or between air gap AG and printed circuit board 1304.

While two separately controlled thermoelectric heat pumps 1333a and 1333b are shown by way of example in FIG. 13, any number of separately controlled thermoelectric heat pumps may be provided across a backside of display 1331 to more precisely control a temperature gradient across display 1331. According to still other embodiments of the present invention, a single thermoelectric heat pump (e.g., heat pump 1333a) may be provided as an active thermal barrier at one end of display 1331 to reduce a temperature gradient without requiring a second thermoelectric heat pump.

As shown in FIG. 14, an electronic device may include a heat generating component 1403 electrically and mechanically coupled to a printed circuit board 1404 and enclosed within a case 1401 (including a transparent region 1401a) together with a display 1431 (such as a liquid crystal display or an organic light emitting diodes (OLED) display). The heat generating component 1403 may be an active electronic heat generating device (e.g., a microelectronic device, a microprocessor, an application specific integrated circuit, a memory, a power amplifier, etc.), and heat from the heat generating component 1403 may conduct through the printed circuit board 1404 and radiate toward display 1431. Accordingly, thermoelectric heat pumps 1433a and 1433b may be provided on printed circuit board 1404 between display 1431 and printed circuit board 1404 to reduce heat flow from printed circuit board 1404 to display 1431 and/or to reduce a temperature gradient across display 1431. Thermoelectric heat pumps 1433a and 1433b may be provided as discussed above with respect to FIGS. 9 and 12 with hot side heat spreaders 1415a and 1415b mechanically coupled to printed circuit board 1404, with cold side heat spreaders 1417a and 1417b adjacent display 1431, and with thermoelectric elements and traces 1416a and 1416b between respective hot and cold side heat spreaders 1415a-b and 1417a-b. Particular arrangements of thermoelectric elements and traces are not repeated in FIG. 13 for ease of illustration. Moreover, an air gap AG and/or a layer of a thermally insulating material (such as aerogel, silicon oxide, etc.) may be provided between cold side heat spreaders 1417a and 1417b and display 1431.

Thermoelectric heat pumps 1433a and 1433b may operate to provide separately controlled active thermal barriers between display 1431 and printed circuit board 1404 (or other heat generating component) in a manier similar to that discussed above with respect to FIGS. 9 and 12 where a thermoelectric heat pump is mechanically coupled to the hotter of the two elements. For example, both of thermoelectric heat pumps 1433a and 1433b may be configured to pump heat in a direction from display 1431 toward printed circuit board 1404, with greater input power and/or current for heat pump 1433a (closer to heat generating component 1403) and lesser input power and/or current for heat pump 1433b (more distant from heat generating component 1403) to reduce a temperature gradient across display 1431. In an alternative, thermoelectric heat pump 1433a may be configured to pump heat in a direction from display 1431 toward printed circuit board 1404 while thermoelectric heat pump 1433b may be configured to pump heat in a direction from printed circuit board 1404 toward display 1431 to reduce a temperature gradient across display 1431. Moreover, efficiencies of thermoelectric heat pumps 1433a and/or 1433b as active thermal barriers may be improved by providing thermal insulation (such as air gap AG) in the paths of heat flow between display 1431 and printed circuit board 1433. While air gap AG is shown by way of example, one or more thermally insulating materials/layers may be provided between cold side heat spreaders 1417a-b and air gap AG, between hot side heat spreaders 1415a-b and printed circuit board 1404, and/or between air gap AG and display 1431.

While two separately controlled thermoelectric heat pumps 1433a and 1433b are shown by way of example in FIG. 14, any number of separately controlled thermoelectric heat pumps may be provided across printed circuit board 1404 to more precisely control a temperature gradient across display 1431. According to still other embodiments of the present invention, a single thermoelectric heat pump (e.g., heat pump 1433a) may be provided as an active thermal barrier on printed circuit board 1404 adjacent one end of display 1431 to reduce a temperature gradient without requiring a second thermoelectric heat pump.

While an active electronic heat generating device on a printed circuit board is shown by way of example in FIGS. 11-14, other arrangements may be provided according to other embodiments of the present invention. For example, the heat generating device may be coupled to a passive heat transfer structure (e.g., a heat sink, a remote heat exchanger, a heat pipe, etc.) in addition to or instead of a printed circuit board, and the thermoelectric heat pump(s) may be provided between portions of the passive heat transfer structure and the display. According to other embodiments of the present invention, the thermoelectric heat pumps may be provided directly between the display and one or more active electronic heat generating devices (e.g., a microelectronic device, a microprocessor, a memory, an application specific integrated circuit, an amplifier, etc.). Moreover, while a display (such as a liquid crystal display or an organic light emitting diodes (OLED) display) is discussed by way of example, thermoelectric heat pumps may be provided as active thermal barriers to reduce heat transfer to other elements of an electronic device according to embodiments of the present invention.

According to embodiments of the present invention discussed above, a thermoelectric heat pump may be operated as an active thermal barrier by pumping heat in a direction that is opposite a direction of a normal thermal heat flow from a heat generating component toward a cooler surface. Stated in other words, the thermoelectric heat pump may be configured to pump heat in a direction from the cooler surface toward the heat generating component to create a temperature inversion opposite of the normal thermal gradient thereby repelling heat back toward the heat generating component. By providing an air gap in series with the thermoelectric heat pump in the thermal path between the cooler surface and the heat generating component, an efficiency of operation of the thermoelectric heat pump as an active thermal barrier may be improved and circulation of air (to dissipate heat from the heat generating device) may be improved. In other words, by providing a hot side of the thermoelectric heat pump at approximately a same temperature as the heat generating component, a transfer of heat from the heat generating component to the surface may be reduced. By providing thermal isolation (using an air gap and/or layer of an insulating material) between the thermoelectric heat pump and the heat generating component and/or between the thermoelectric heat pump and the cooler surface, an amount of current required to produce the desired temperature inversion may be reduced thereby reducing power consumed and/or heat generated by the thermoelectric heat pump. By providing an air gap between the hot side of the thermoelectric heat pump and the heat generating component, air flow from a cooling fan may be used to dissipate heat from the heat generating component.

While a controller is not separately shown in each of FIGS. 8, 9, 11, 12, 13, or 14 for clarity of illustration, it will be understood that a controller may be coupled to each of the thermoelectric heat pumps to provide input power and/or current required for heat pumping. Where multiple thermoelectric heat pumps are provided (e.g., thermoelectric heat pumps 1333a and 1333b of FIG. 13 or thermoelectric heat pumps 1433a and 1433b of FIG. 14), the controller may separately control the different heat pumps with different input powers and/or currents to provide different rates and/or directions of heat pumping. For example, different magnitudes of input power and/or current of the same polarity may be provided to the different thermoelectric heat pumps to provide different effective barriers to heat transfer, or different polarities of input power and/or current may be provided to the different thermoelectric heat pumps to provide heat pumping in opposite directions. By separately controlling different thermoelectric heat pumps between two elements, for example, a more uniform temperature across on the elements (such as a display) may be reduced.

Thermoelectric devices, structures, assemblies, and methods of fabrication/assembly/deposition/operation thereof are discussed by way of example, in: U.S. Pat. Pub. No. 2002/0174660 entitled “Thin-Film Thermoelectric Cooling And Heating Devices For DNA Genomic And Proteomic Chips, Thermo-Optical Switching Circuits, And IR Tags”; U.S. Pat. Pub. No. 2003/0099279 entitled “Phonon-Blocking, Electron-Transmitting Low-Dimensional Structures”; U.S. Pat. Pub. No. 2003/0230332 entitled “Thermoelectric Device Utilizing Double-Sided Peltier Junctions And Method Of Making The Device”; U.S. Pat. Pub. No. 2006/0225773 entitled “Trans-Thermoelectric Device”; U.S. Pat. Pub. No. 2006/0086118 entitled “Thin film thermoelectric devices for hot-spot thermal management in microprocessors and other electronics”; U.S. Pat. Pub. No. 2006/0243317 entitled “Thermoelectric Generators For Solar Conversion And Related Systems And Methods”; U.S. Pat. Pub. No. 2006/0289052 entitled “Methods Of Forming Thermoelectric Devices Including Conductive Posts And/Or Different Solder Materials And Related Methods And Structures; U.S. Pat. Pub. No. 2006/0289050 entitled “Methods Of Forming Thermoelectric Devices Including Electrically Insulating Matrixes Between Conductive Traces And Related Structures”; U.S. Pat. Pub. No. 2007/0089773 entitled “Methods Of Forming Embedded Thermoelectric Coolers With Adjacent Thermally Conductive Fields And Related Structures”; U.S. Pat. Pub. No. 20070028956 entitled “Methods Of Forming Thermoelectric Devices Including Superlattice Structures Of Alternating Layers With Heterogeneous Periods And Related Devices”; U.S. Pat. Pub. No. 2007/0215194 entitled “Methods Of Forming Thermoelectric Devices Using Islands Of Thermoelectric Material And Related Structures”; U.S. Pat. Pub. No. 2008/0185030 entitled “Methods Of Depositing Epitaxial Thermoelectric Films Having Reduced Crack And/Or Surface Defect Densities And Related Devices”; U.S. Pat. Pub. No. 2008/0168775 entitled “Temperature Control Including Integrated Thermoelectric Temperature Sensing And Related Methods And Systems”; U.S. Pat. Pub. No. 2008/0264464 entitled “Temperature Control Including Integrated Thermoelectric Sensing And Heat Pumping Devices And Related Methods And Systems”; and U.S. Pat. Pub. No. 2009/0000652 entitled “Thermoelectric Structures Including Bridging Thermoelectric Elements”. The disclosures of all of the above referenced patent publications are hereby incorporated herein in their entirety by reference.

While the present invention has been particularly shown and described with reference to embodiments thereof, it will be understood by those of ordinary skill in the art that various changes in form and details may be made therein without departing from the spirit and scope of the present invention as defined by the following claims.

That which is claimed is:

1. An electronic device comprising:
a heat generating component;
a surface adjacent the heat generating component wherein a temperature of the heat generating component is greater than a temperature of the surface adjacent the heat generating component during operation of the electronic device; and
a thermoelectric heat pump between the surface and the heat generating component wherein the thermoelectric heat pump is configured to pump heat from a cold side of the thermoelectric heat pump adjacent the surface toward the heat generating component.

2. An electronic device according to claim 1 wherein the surface comprises a portion of a surface of a case enclosing the heat generating component therein so that the thermoelectric heat pump is configured to pump heat from the cold side adjacent the portion of the surface of the case toward the heat generating device.

3. An electronic device according to claim 1 wherein the surface comprises a surface of a backside of a display so that the thermoelectric heat pump is configured to pump heat from the cold side adjacent the surface of the backside of the display toward the heat generating device.

4. An electronic device according to claim 1 wherein the thermoelectric heat pump comprises a plurality of thermoelectric elements thermally coupled in parallel between the heat generating component and the surface so that an electrical current through the plurality of thermoelectric elements pumps heat from the cold side of the thermoelectric heat pump toward the heat generating component.

5. An electronic device according to claim 4 wherein the thermoelectric elements comprises n-type and p-type thermoelectric elements that are alternatingly electrically connected in series so that a direction of current through the n-type thermoelectric elements relative to heat flow is opposite a direction of current flow through the p-type thermoelectric elements relative to heat flow.

6. An electronic device according to claim 4 wherein the thermoelectric heat pump comprises a hot side heat spreader wherein the plurality of thermoelectric elements are thermally coupled in parallel between the hot side heat spreader and the surface and wherein the hot side heat spreader is between the plurality of thermoelectric elements and the heat generating component.

7. An electronic device according to claim 6 wherein the hot side heat spreader is spaced apart from the heat generating component to provide a thermally insulating gap therebetween.

8. An electronic device according to claim 4 wherein the thermoelectric heat pump comprises a cold side heat spreader wherein the plurality of thermoelectric elements are thermally coupled in parallel between the cold side heat spreader and the heat generating component and wherein the cold side heat spreader is between the plurality of thermoelectric elements and the surface.

9. An electronic device according to claim 8 wherein the cold side heat spreader is spaced apart from the surface to provide a thermally insulating gap therebetween.

10. An electronic device according to claim 1 wherein the heat generating component comprises an active heat generating electronic device.

11. An electronic device according to claim 1 wherein the heat generating component comprises a passive heat generating source.

12. An electronic device according to claim 1 wherein the thermoelectric heat pump comprises a first thermoelectric heat pump, the electronic device further comprising:
a second thermoelectric heat pump between the surface and the heat generating component wherein the second thermoelectric heat pump is configured to pump heat from a cold side of the second thermoelectric heat pump adjacent the heat generating component toward the surface.

13. An electronic device according to claim 1 wherein the thermoelectric heat pump comprises a first thermoelectric heat pump configured to pump heat toward the heat generating device responsive to a first input power and/or current, the electronic device further comprising:
a second thermoelectric heat pump between the surface and the heat generating component wherein the second thermoelectric heat pump is configured to pump heat from a cold side of the second thermoelectric heat pump adjacent the surface toward the heat generating component responsive to the second input power and/or current, wherein the first input power and/or current and the second input power and/or current are different.

14. A method of operating an electronic device including a heat generating component and a surface adjacent the heat generating component, wherein a temperature of the heat generating component is greater than a temperature of the surface, the method comprising:
thermoelectrically pumping heat from a cold side of a thermoelectric heat pump adjacent the surface toward the heat generating component wherein the thermoelectric heat pump is between the surface and the heat generating component.

15. A method according to claim 14 wherein the surface comprises a portion of a surface of a case enclosing the heat generating component therein so that the thermoelectrically pumping heat comprises thermoelectrically pumping heat from the cold side adjacent the portion of the surface of the case toward the heat generating device.

16. A method according to claim 14 wherein the surface comprises a surface of a backside of a display so that thermoelectrically pumping comprises thermoelectrically pumping heat from the cold side adjacent the surface of the backside of the display toward the heat generating device.

17. A method according to claim 14 wherein thermoelectrically pumping heat comprises providing an electrical current through a plurality of thermoelectric elements that are thermally coupled in parallel between the heat generating component and the surface to thermoelectrically pump heat away from the surface and toward the heat generating component.

18. A method according to claim 17 wherein the thermoelectric elements comprises n-type and p-type thermoelectric elements that are alternatingly electrically connected in series so that a direction of the current through the n-type thermoelectric elements relative to heat flow is opposite a direction of the current through the p-type thermoelectric elements relative to heat flow.

19. A method according to claim 14 wherein the heat generating component comprises an active heat generating electronic device.

20. A method according to claim 14 wherein the heat generating component comprises a passive heat generating source.

21. A method according to claim 14 wherein the thermoelectric heat pump comprises a first thermoelectric heat pump, wherein the electronic device includes a second thermoelectric heat pump between the surface and the heat generating component, the method further comprising:
thermoelectrically pumping heat from a cold side of the second thermoelectric heat pump adjacent the heat generating component toward the surface while thermoelectrically pumping heat from the cold side of the first thermoelectric heat pump toward the heat generating component.

22. A method according to claim 14 wherein the thermoelectric heat pump comprises a first thermoelectric heat pump configured to pump heat toward the heat generating device responsive to a first input power and/or current, wherein the electronic device includes a second thermoelectric heat pump between the surface and the heat generating component, the method further comprising:
thermoelectrically pumping heat from a cold side of the second thermoelectric heat pump adjacent the surface toward the heat generating component responsive to a second input power and/or current while thermoelectrically pumping heat from the cold side of the first thermoelectric heat pump toward the heat generating component wherein the first input power and/or current and the second input power and/or current are different.
